(19) United States
(12) Patent Application Publication
(10) Pub. No.: US 2024/0405459 A1
(43) Pub. Date: Dec. 5, 2024

(54) Modular Printed Circuit Boards with Connectors

(71) Applicant: Intel Corporation, Santa Clara, CA (US)

(72) Inventors: Navneet K. SINGH, Bangalore (IN); Aiswarya PIOUS, Bangalore (IN); Samarth ALVA, Bangalore (IN); Sharvil DESAI, Ahmedabad (IN); Ralph JENSEN, Hillsboro, OR (US); Carlos MARISCAL, Gresham, OR (US); Michael CROCKER, Portland, OR (US); Kevin MA, Beaverton, OR (US); Pedro Jose MARTINEZ NARVAEZ, Hillsboro, OR (US)

(21) Appl. No.: 18/327,100

(22) Filed: Jun. 1, 2023

(51) Int. Cl. H01R 12/52; H05K 3/36

(52) U.S. Cl. CPC H01R 12/52; H05K 3/368

(57) ABSTRACT

According to the various aspects, the present disclosure is directed to printed circuit board assemblies having a plurality of printed circuit board units or modules that use board connectors for joining the printed circuit board units. In an aspect, the board connector has a first surface, which may be a top surface, and an opposing second surface, which may be a bottom surface, and a plurality of openings, including a first set of connector openings for providing electrical connections between the at least two plurality of printed circuit board units. In another aspect, a method that includes forming a first printed circuit board unit with a first connecting portion and a second printed circuit board unit with a second connecting portion, and the first and second connecting are electrically coupled with the printed circuit board connector.

### BACKGROUND

For integrated circuit design and fabrication, the need to improve performance and lower costs are constant challenges. As transistors continue to shrink in size and die become larger due to increased functionalities, it is becoming more and more difficult and costly to realize high-volume manufacturing of semiconductor devices. Cost savings may be potentially realized by building dies on individual discrete printed circuit boards (PCB) rather than a single large PCB. Furthermore, PCBs are also one of the major contributors to the carbon footprint of semiconductor devices, mostly from the need for soldering. And recently, reducing the carbon footprint of semiconductor devices, as well as contributing to environmental sustainability, have become equally important objectives along with the need for performance improvements and the reduction of costs.

For the laptop market, miniaturizing the components of a system design and reducing the PCB size are the most challenging aspects of designing thin and compact laptops. Such laptop system designers need universal motherboard/PCB solutions that may be applied across various laptop segments (e.g., ultra-thin performance, creator, gaming, etc.) in their system designs without giving up on performance. On the other hand, there are certain market segments (e.g., servers, industrial applications, etc.) that may need large PCBs. These system designers need scalable solutions that may reduce the need for reflow soldering and may be applied to their particular market segments of large system designs. The conventional design and manufacturing approaches currently being used are unable to provide a universal and scalable printed circuit board design approach for laptop and large PCB designers that offer the possibility of design flexibility, cost-saving, re-usability for selected electronic components, and environmental sustainability.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIGS. 1A and 1B show an exemplary representation of two printed circuit board units and printed circuit board connector forming a printed circuit board assembly according to an aspect of the present disclosure;

FIGS. 2A, 2B, 2C, 2D, and 2E show exemplary representations of two discrete printed circuit boards having attached dies that are joined by a printed board connector according to another aspect of the present disclosure;

FIGS. 3, 3A, 3B and 3C show an exemplary representation of a large printed circuit board assembly and its constituent parts according to an aspect of the present disclosure;

FIGS. 4A and 4B show an exemplary representation of conductive materials filling connector openings according to another aspect of the present disclosure;

FIGS. 5A, 5B, 5C, 5D, and 5E show an exemplary representation of aligning and forming an electrical connection for a printed circuit board assembly according to an aspect of the present disclosure; and

FIG. 6 shows a simplified flow diagram for an exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for the present printed board assemblies, and various aspects are provided for the methods. It will be understood that the basic properties of the present printed board assemblies also hold for the methods and vice versa. Other aspects may be utilized for structural and logical changes without departing from the scope of the present disclosure. The various aspects are not necessarily mutually exclusive, as some aspects can be combined with one or more other aspects to form new aspects.

The present disclosure relates to modular print circuit board (PCB) solutions that enable the cost-efficient connecting of discrete PCB units or sub-components using unique printed circuit board connectors, i.e., various types of molded array solder connections (MASC). The present solution may be scaled for assembling various device modules, such as discrete-graphics processing units (d-GPU), which may provide “plug-n-play” options for multiple brands or “flavors” of d-GPU modules.

According to the present disclosure, the printed circuit board connector may be a MASC interposer/layer between, for example, the printed circuit board of a central processing unit (CPU) module and a graphics processing unit (GPU) module. The present MASC interposer may be provided with a conductive material (e.g., solder) that is deposited on the interposer for vertically connecting the two modules. The manufacture of the present printed circuit assemblies will be cost-efficient, as there will be no tedious fabrication process required.

The present disclosure is directed to a printed circuit board assembly having a plurality of printed circuit board units or modules and a board connector for joining at least two of the plurality of printed circuit board units. In an aspect, the board connector has a first surface, which may be a top surface, and an opposing second surface, which may be a bottom surface, and a plurality of openings, including a first set of connector openings for providing electrical connections between the at least two printed circuit board units.

In another aspect, the present disclosure is directed to a method that includes forming a first printed circuit board unit with a first connecting portion and a second printed circuit board unit with a second connecting portion and forming a printed circuit board connector having a first surface and an opposing second surface. The method further includes electrically coupling the first connecting portion of the first printed circuit board unit with the first surface of the printed circuit board connector and electrically coupling the second connection portion of the second printed circuit board unit with the first surface or the second surface of the printed circuit board connector, which will depend on the alignment of the first and second connecting portions.

In a further aspect, the present disclosure is directed to a printed circuit board connector having a first surface, which may be a top surface, and an opposing second surface, which may be a bottom surface. There are a plurality of openings formed in the printed circuit board connector, including a first set of connector openings that is provided with an electrically conductive material for coupling at least two printed circuit board units.

The technical advantages of the present disclosure include, but are not limited to:
(i) Providing a modular solution to manufacture printed circuit board (PCB) assemblies using one or more board connectors, such as MASC interposers, to enable configurable options that meet the requirements of various market segments;
(ii) Providing PCBs that enable “plug-n-play” variations for d-GPU modules that may reduce the design time for laptop designers;
(iii) Providing flexibility in designing PCB with a variety of form factors through the use of board connectors that have a variety of form factors; and
(iv) Providing various configurable PCB options using the present board connectors to create modular system designs that permit the use of replaceable components to align with sustainability goals.

To more readily understand and put into practical effect the present printed circuit assembly structures and method for constructing these assemblies, which may be used for improving sustainability and performance, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

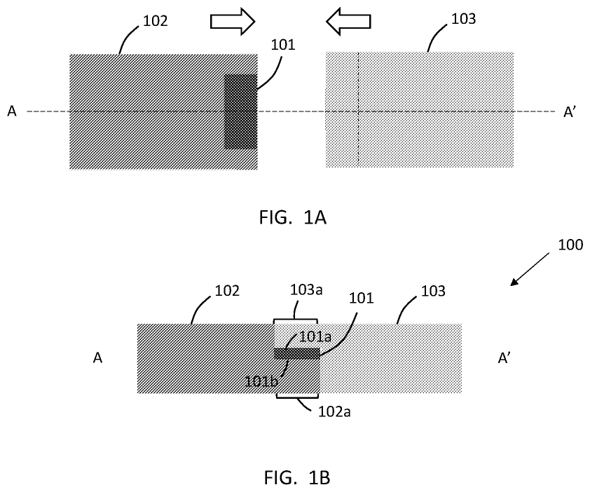

FIGS. 1A and 1B show an exemplary representation of first and second printed circuit board units 102 and 103 that are joined by a printed circuit board connector 101 to form a printed circuit board assembly 100 according to an aspect of the present disclosure. FIG. 1B shows a cross-sectional view along the A-A′ line of FIG. 1A. In an aspect, the first printed circuit board unit 102 may have a first connecting portion 102a and the second printed circuit board unit may have a second connecting portion 103a. In a further aspect, the first connecting portion 102a may be pre-positioned and coupled to a bottom surface 101b of the printed circuit board connector 101, and the second connection portion 103a may be coupled to a top surface 101a of the printed circuit board connector 101.

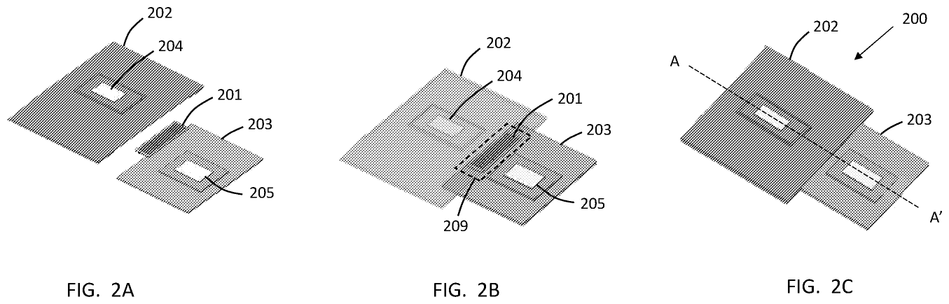

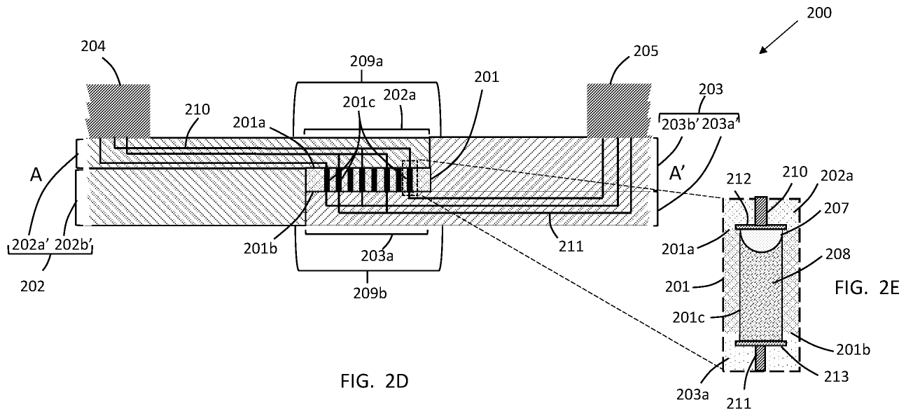

According to the present disclosure, the printed board connector 101, a.k.a. a board connector, may be a molded array solder connection (MASC). The MASC may be an interposer or layer that is fabricated using an FR-4 or FR-5 material by a conventional manufacturing process (e.g., a molding or printing process). The present MASC interposer may not require electrical conductors since, in most instances, the electrical connection may be provided by the connector openings, as shown in FIG. 2E below. The FR-4 and FR-5 are composite materials composed of woven fiberglass cloth with an epoxy resin binder. The FR-5 material has a higher temperature tolerance than the FR-4 material and may be used when higher temperature tolerances are needed. The FR-4 or FR-5 material used to fabricate the printed board connector 101 may have a composition that has a coefficient of thermal expansion (CTE) that is equivalent to or closely matches the CTEs for the adjoining PCB units that are being connected. In another aspect, the printed circuit board units may also be fabricated using an FR-4 or FR-5 material.

In an aspect, the printed board connector or MASC interposer 101 may have different thicknesses/heights depending on a PCB layout design. A printed board connector height may be in the range of approximately 0.2 mm to 3.2 mm; in particular, in the range of approximately 0.9 mm to 1.5 mm. As shown in the accompanying figures, the present printed board connector or MASC interposer may be designed in various shapes, sizes, and thicknesses, as required for a particular PCB design. In addition, the printed circuit board units may have various shapes, sizes, and thicknesses, as required for a particular PCB design.

FIGS. 2A, 2B, 2C, 2D, and 2E show exemplary representations of two discrete printed circuit board units with dies being joined by a printed board connector according to another aspect of the present disclosure. A first printed circuit board unit 202 may have a die 204 and a second printed circuit board unit 203 may have a die 205 that is joined by a printed board connector 201. In this aspect, the printed board connector 201 may be a MASC interposer layer, the first printed circuit board unit 202 with the die 204 may form a CPU module, and the second printed circuit board unit 203 with the die 205 may form a discrete GPU or d-GPU module. The printed board connector 201 provides the electrical connections between the first printed circuit board unit 202 and the second printed circuit board unit 203, which thereby connects the CPU with the GPU.

In FIGS. 2A, 2B, and 2C, a simplified assembly process for the CPU module and the d-GPU module using a MASC interposer to form a printed circuit board assembly 200 is shown. In this aspect, the first printed circuit board unit 202 may be positioned over the printed board connector/MASC interposer layer 201, while the second printed circuit board unit 203 may be positioned under the printed board connector/MASC interposer layer 201 to form an overlapping stack. In addition, a keep-out zone (KOZ) 209 may be provided above, as well as below, the printed board connector 201 to provide space to accommodate clamping billets and other tooling hardware to enable, for example, reflow soldering and/or the electrical coupling between the first printed circuit board unit 202, the printed board connector/MASC interposer layer 201, and the second printed circuit board unit 203. It should be understood that the positioning of the PCB units in relation to the printed circuit board interconnector(s) may be based on a particular design layout and other considerations. In an aspect, the first printed circuit board unit 202 may be the “main” board, and the second printed circuit board unit 203 may be a secondary board.

With the present approach, a low-cost modular solution is available to accommodate the assembly of a variety of brands of d-GPU modules, which is approximately 30% to 40% more cost-efficient than using a board-to-board connector with flexible printed circuits. By enabling a “plug-n-play” d-GPU module option for laptop designers, it may reduce the design time for laptop designers and provide greater flexibility for manufacturers.

In another aspect, the printed circuit board assembly 200 is shown in greater detail in FIG. 2D, which provides a cross-sectional view along the A-A′ section line of FIG. 2C. As shown in FIG. 2D, the first printed circuit board unit 202 with the die 204, which may form a CPU module, and the second printed circuit board unit 203 with the die 205, which may form a discrete GPU or d-GPU module, are joined together by the printed board connector/MASC interposer 201. In an aspect, the first printed circuit board unit 202 may include a first upper layer 202a′ and a first bottom layer 202b′, and the second printed circuit board unit 203 may include a second upper layer 203b′ and a second bottom layer 203a′.

In another aspect, the first upper layer 202a′ of the first printed circuit board unit 202 may include a plurality of routing/signal lines 210, and the second bottom layer 203a′ of the second printed circuit board unit 203 may include a plurality of routing signal lines 211. In addition, the first upper layer 202a′ may have a first connecting portion 202a, and the second bottom layer 203a′ may have a second connecting portion 203a. The first connecting portion 202a may be disposed on and electrically coupled to a first or top surface 201a of the printed board connector/MASC interposer 201, and the second connecting portion 203a may be disposed on and electrically coupled to a second or bottom surface 201b of the printed board connector/MASC interposer 201. In addition, a top KOZ 209a may be provided over the first upper layer 202a′ and a bottom KOZ 209b may be provided under the second bottom layer 203a′. This configuration enables the physical and electrical joining of the first printed circuit board unit 202 with the second printed circuit board unit 203.

In another aspect, the printed board connector/MASC interposer 201 may have a plurality of first connector openings 201c, which may be positioned as an array. As shown in FIG. 2E, the plurality of first connector openings 201c may be filled with a conductive material 208. In a further aspect, the conductive material 208 may include a mixture of silver and copper particles and a silicone polymer, which is a conductive elastomeric material that allows for assembly with a discrete PCB unit according to the present disclosure. In addition, the use of conductive elastomeric materials may enable multiple assembly and disassembly of printed circuit board units for modular system designs that may permit the use of replaceable components that comports with sustainability goals.

Also, in an aspect shown in FIG. 2E, the routing lines 210 in the first connecting portion 202a may have a plurality of contact pads 212 that have solder material 207 positioned for connecting with the conductive material 208. In another aspect, as shown in FIG. 2E, the second connecting portion 203a may have a plurality of contact pads 213 that connect directly with the conductive material 208. As shown, the conductive material 208 may be recessed from the top surface 201a of the printed board connector/MASC interposer 201, when using a solder material, and/or extended beyond the bottom surface 201b of the printed board connector/MASC interposer 201, when connecting directly to a contact pad 213.

With the present approach, low-cost modular solutions with denser routings are possible such that they do not impact the printed circuit board area, i.e., require more space, when accommodating various types of d-GPU modules. In addition, the present modular solutions will allow the manufacture of printed circuit board (PCB) assemblies using two or more board connectors, such as MASC interposers, to enable configurable options that meet the requirements of other market segments as described below.

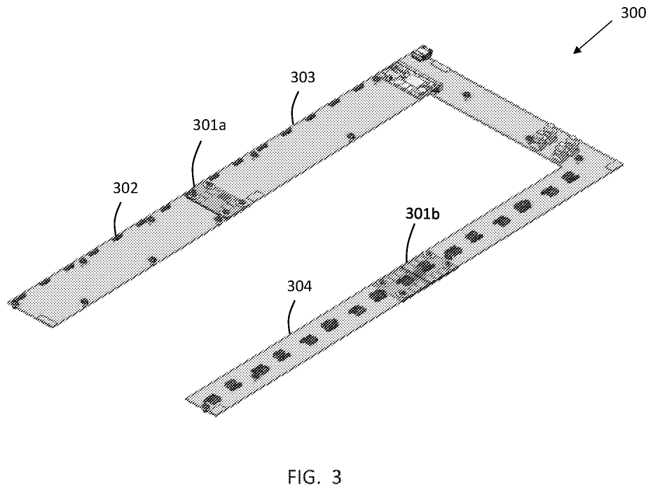

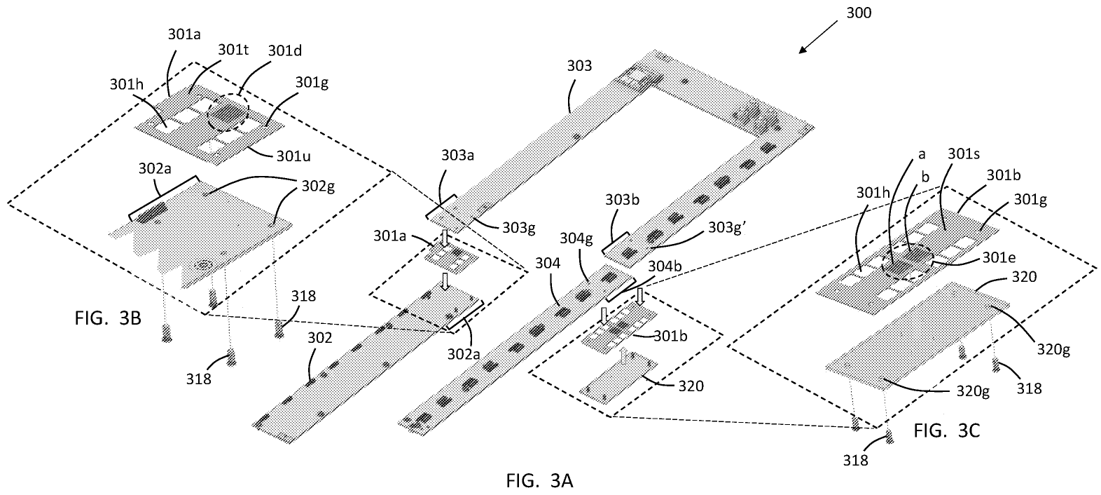

FIGS. 3, 3A, 3B, and 3C show an exemplary representation of a “large” printed circuit board assembly and its constituent parts according to another aspect of the present disclosure. Generally, a printed circuit board that is more than 12 inches wide is considered large. At 30 inches wide, the limitations of the automated surface mount technology assembly systems have been reached and alternative manufacturing methods must be considered. For example, a market segment that uses Programmable & Integrated Unified Memory Architecture (PIUMA) for large-scale graph analytics may require large PCBs.

According to the present disclosure, as shown in FIG. 3, a printed circuit board assembly 300 is a large PCB designed to accommodate PIUMA sleds of mezzanine accelerators along with their laser module counterparts. The printed circuit board assembly 300 may have a first PCB unit 302, a second PCB unit 303, and a third PCB unit 304, as well as first and second printed circuit board connectors 301a and 301b, respectively. The assembly of the printed circuit board assembly 300 is shown in FIGS. 3A, 3B, and 3C.

In FIG. 3A, the printed circuit board assembly 300 includes the first PCB unit 302 having a first connecting portion 302a that is coupled to a bottom surface 301u (shown in FIG. 3B) of the printed circuit board connectors 301a, and the second PCB unit 303 has a second connecting portion 303a at a first end that is coupled to a top surface 301t (shown in FIG. 3B) of the printed circuit board connectors 301a. The first connecting portion 302a, the printed circuit board connectors 301a, and the second connecting portion 303a form an overlapping stack that joins the first and second PCB units 302 and 303, respectively.

In an expanded view shown in FIG. 3B, the printed circuit board connector 301a may have a first set of connector openings 301d that are filled with electrically conductive material for providing an array of electrical connections between the first and second PCB units 302 and 303, respectively, a second set of connector openings 301g for alignment and attachment, and a plurality of solder openings 301h, which may be used for power delivery. The first connecting portion 302a and the second connecting portion 303a will have electrical connections (which are all not shown) that correspond to the first set of connector openings on the printed circuit board connector 301a and the plurality of solder opening 301h.

In addition, a first set of connector openings 302g in the first connecting portion 302a, the second set of connector openings 301g in the printed circuit board connector 301a, and a first set of connector openings 303g in the second connecting portion 303a at the first end may be aligned to allow the positioning of alignment/attachment members 318 for the removable attachment and stability of the overlapping stack.

In another aspect, as shown in FIG. 3A, the printed circuit board assembly 300 also includes the third PCB unit 304 having a first connecting portion 304b that is coupled to a top surface 301s of a second printed circuit board connector 301b, and the second PCB unit 303 has a second connecting portion 303b at a second end that is also coupled to the top surface 301s of the second printed circuit board connector 301b.

In an expanded view shown in FIG. 3C, the second printed circuit board connector 301b may include a first set of connector openings 301e that form a first portion “a” and a second portion “b” that are filled with electrically conductive material for providing an array of electrical connections between the second and third PCB units 303 and 304, respectively, a second set of connector openings 301g for alignment and attachment, and a plurality of solder openings 301h, which may be used for power delivery. The first connecting portion 304b of the third PCB unit 304 and the second connecting portion 303a at the second end of the second PCB unit 303 will have electrical connections that correspond, respectively, to the first portion “a” and the second portion “b” of the first set of connector openings 301e on the second printed circuit board connector 301b, and the plurality of solder opening 301h (which are all not shown).

In another aspect, a bridge board 320 may be positioned under the second printed circuit board connectors 301b to provide added support to the connections between the second and third PCB units 303 and 304, respectively. The bridge board 320 may have a first set of connector openings 320g that are aligned with a first set of connector openings 303g′ at the second connecting portion 303b at the second end of the second PCB unit 303, the second set of connector openings 301g in the printed circuit board connectors 301b, and a first set of connector openings 304g in the first connecting portion 304b to allow the positioning of alignment/attachment members 318 for the removable attachment and stability of these overlapping units.

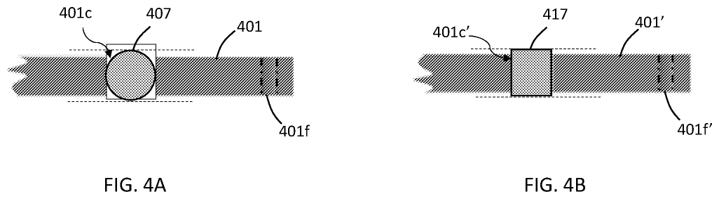

FIGS. 4A and 4B show an exemplary representation of electrically conductive materials filling connector openings in printed circuit board connectors according to another aspect of the present disclosure. In FIG. 4A, a partial view of a printed circuit board connector 401 is shown. The printed circuit board connector 401 may have a first connector open 401c that is filled with an electrically conductive material, such as solder ball 407, positioned in the first connector open 401c. The solder ball 407 may have a dimension that is greater than the depth of the first connector open 401c to enable connectivity with PCB units. In addition, an alignment opening 401f may be provided on the printed circuit board connector 401.

In FIG. 4B, another partial view of a printed circuit board connector 401′ is shown. The printed circuit board connector 401′ may have a first connector open 401c′ that is filled with a pre-formed electrically conductive material 417, which may be made of a solder paste or conductive elastomer, positioned in the first connector open 401c′. The pre-formed electrically conductive material 417 may also have a dimension that is greater than the depth of the first connector open 401c′ to enable connectivity with PCB units. In addition, an alignment opening 401f may be provided on the printed circuit board connector 401′.

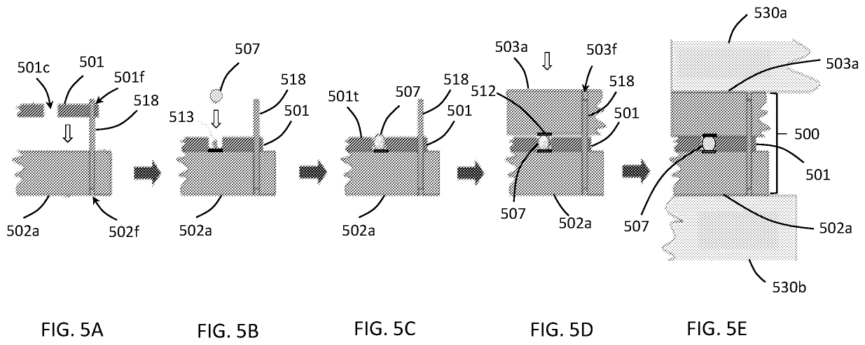

According to an aspect of the present disclosure, FIGS. 5A, 5B, 5C, 5D, and 5E show an exemplary method for aligning two printed circuit board units and forming an electrical connection therebetween for a printed circuit board assembly 500. In FIG. 5A, a first printed circuit board unit 502a may have an alignment opening 502f, in which an alignment member 518 is positioned. Further to this method, a board connector 501, having a connection opening 501c and an alignment opening 501f, may be positioned over the first printed circuit board unit 502a and the alignment member 518 positioned in the alignment opening 501f.

In FIGS. 5B and 5C, a first contact pad 513 may be formed in the connection opening 501c, and thereafter, a solder ball 507 may also be positioned in the connection opening 501c on the first contact pad 513. The solder ball 507, which is one of a plurality of solder balls, may have a dimension that allows it to protrude above a first or top surface 501t of the board connector 501.

In FIG. 5D, a second printed circuit board unit 503a with an alignment opening 503f may be positioned over the board connector 501 and the alignment member 518 positioned in the alignment opening 503f. The second printed circuit board unit 503a is positioned so that the solder ball 507 is coupled with a second contact pad 512 positioned on the second printed circuit board unit 503a.

In FIG. 5E, a heat press tool (not shown) with an upper plate 530a and lower plate 530b may be used to apply heat and pressure to join the stack formed by the first printed circuit board unit 502a, the board connector 501, and the second printed circuit board unit 503a.

The foregone method provides for the use of self-aligned contacts (SAC) between the first printed circuit board unit 502a, the board connector 501, and the second printed circuit board unit 503a, which are coupled by aligned pluralities of first contact pads 513, solder balls 507, and second contact pads 512, and the alignment member 518 may be positioned in the alignment openings 502f, 501f, and 503f to facilitate the alignment. In another aspect, a SAC coupling process for the printed circuit board units may use a low-temperature soldering process, which may reduce surface-mount technology temperatures from, for example, a typical range of 220-260° C. to a lead-free process using a temperature of approximately 190° C. It should be understood that the method shown in FIGS. 5A to 5E applies equally to the use of pre-formed electrically conductive material, as shown in FIG. 4B above.

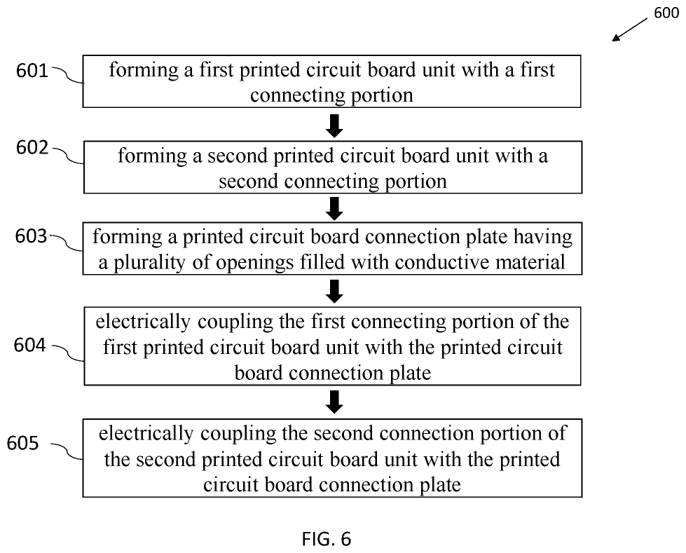

FIG. 6 shows a simplified flow diagram for an exemplary method according to an aspect of the present disclosure.

The operation 601 may be directed to forming a first printed circuit board unit with a first connecting portion, for which a shorter first layer may be attached to a longer second layer.

The operation 602 may be directed to forming a second printed circuit board unit with a second connecting portion, for which a shorter first layer may be attached to a longer second layer.

The operation 603 may be directed to forming a printed circuit board connection plate/board connector having a plurality of openings filled with conductive material.

The operation 604 may be directed to electrically coupling the first connecting portion of the first printed circuit board unit with the printed circuit board connection plate, for which the first printed circuit board unit is aligned with the printed circuit board connection plate.

The operation 605 may be directed to electrically coupling the second connection portion of the second printed circuit board unit with the printed circuit board connection plate, for which the second printed circuit board unit is aligned with the printed circuit board connection plate.

It will be understood that any property described herein for a particular printed circuit assembly and method for forming a printed circuit assembly may also hold for any printed circuit assembly described herein. It will also be understood that any property described herein for a specific method may hold for any of the methods described herein. Furthermore, it will be understood that for any printed circuit assembly and the methods described herein, not necessarily all the components or operations described will be shown in the accompanying drawings or method, but only some (not all) components or operations may be disclosed.

To more readily understand and put into practical effect the present printed circuit assemblies, they will now be described by way of examples. For the sake of brevity, duplicate descriptions of features and properties may be omitted.

### Examples

Example 1 provides a printed circuit board assembly including a plurality of printed circuit board units, and a board connector for joining at least two of the plurality of printed circuit board units, the board connector includes a first surface and an opposing second surface, a plurality of openings, for which the plurality of openings includes a first set of connector openings for providing electrical connections between at least two plurality of printed circuit board units.

Example 2 may include the printed circuit board assembly of example 1 and/or any other example disclosed herein, for which the plurality of printed circuit board units includes a first printed circuit board unit having a first connecting portion, for which the first connecting portion of the first printed circuit board unit is electrically coupled to the first surface of the board connector, and a second printed circuit board unit having a second connecting portion, for which the second connecting portion of the second printed circuit board unit is electrically coupled to the second surface of the board connector.

Example 3 may include the printed circuit board assembly of example 2 and/or any other example disclosed herein, for which the first connecting portion includes a first set of connecting portion openings for alignment and attachment with the board connector, for which the second connecting portion includes a second set of connecting portion openings for providing alignment and attachment with the board connector, and the board connector further includes a second set of connector openings that is aligned with both the first set of connecting portion openings in the first connecting portion of the first printed circuit board unit and the second set of connecting portion openings in the second connecting portion of the second printed circuit board unit.

Example 4 may include the printed circuit board assembly of example 3 and/or any other example disclosed herein, further includes a plurality of alignment members, for which the first set of connecting portion openings, the second set of connector openings, and the second set of connecting portion openings are aligned to form a set of stacked openings, and for which the plurality of alignment members is positioned in the set of stacked openings.

Example 5 may include the printed circuit board assembly of example 1 and/or any other example disclosed herein, for which the plurality of printed circuit board units includes a first printed circuit board unit having a first connecting portion, for which the first connecting portion is electrically coupled to the first surface of the board connector, and a second printed circuit board unit having a second connecting portion, for which the second connecting portion is electrically coupled to the first surface of the board connector.

Example 6 may include the printed circuit board assembly of example 5 and/or any other example disclosed herein, for which the first connecting portion includes a first set of connecting portion openings for alignment and attachment with the board connector, and the second connecting portion includes a second set of connecting portion openings for providing alignment and attachment with the board connector, and the board connector further includes a second set of connector openings that is aligned with both the first set of connecting portion openings in the first connecting portion of the first printed circuit board unit and the second set of connecting portion openings in the second connecting portion of the second printed circuit board unit.

Example 7 may include the printed circuit board assembly of example 6 and/or any other example disclosed herein, further includes a bridge board having a plurality of bridge board openings, for which the bridge board is positioned on the second surface of the board connector.

Example 8 may include the printed circuit board assembly of example 7 and/or any other example disclosed herein, further includes a plurality of alignment members, for which the first set of connecting portion openings, a first portion of the second set of connector openings, and a first portion of the plurality of bridge board openings are aligned to form a first set of stacked openings, and for which the second set of connecting portion openings, a second portion of the second set of connector openings, and a second portion of the plurality of bridge board openings are aligned to form a second set of stacked openings, and for which the plurality of alignment members is positioned in the first and second stacked openings.

Example 9 may include the printed circuit board assembly of example 2 and/or any other example disclosed herein, for which the first printed circuit board unit includes a central processing unit

Example 10 may include the printed circuit board assembly of example 9 and/or any other example disclosed herein, for which the second printed circuit board unit includes a discrete graphics processing unit or d-GPU.

Example 11 may include the printed circuit board assembly of example 1 and/or any other example disclosed herein, for which the plurality of printed circuit board units includes at least three printed circuit board units for providing electrical connections and mechanical support to electrical components for parallel pre-fix scan operations.

Example 12 may include the printed circuit board assembly of example 1 and/or any other example disclosed herein, further includes an electrically conductive material filling the first set of openings in the board connector, for which the electrically conductive material protrudes beyond the first and second surfaces of the board connector.

Example 13 provides a method including forming a first printed circuit board unit with a first connecting portion, forming a second printed circuit board unit with a second connecting portion, forming a printed circuit board connector having a first surface and an opposing second surface, electrically coupling the first connecting portion of the first printed circuit board unit with the first surface of the printed circuit board connector, and electrically coupling the second connection portion of the second printed circuit board unit with the first surface or the second surface of the printed circuit board connector.

Example 14 may include the method of example 13 and/or any other example disclosed herein, which further includes forming openings in the print circuit board connector and filling the openings with an electrically conductive material, for which the electrically conductive material protrudes beyond the first and second surfaces of the printed circuit board connector.

Example 15 may include the method of example 13 and/or any other example disclosed herein, further includes forming openings for alignment in the first connecting portion of the first printed circuit board unit, the second connection portion of the second printed circuit board unit, and the printed circuit board connector, aligning the openings in the first connecting portion of the first printed circuit board unit with the openings in the printed circuit board connector, and aligning the openings in the second connecting portion of the second printed circuit board unit with the openings in the printed circuit board connector.

Example 16 provides a printed circuit board connector including a first surface and an opposing second surface, a plurality of openings formed in the printed circuit board connector, for which the plurality of openings includes a first set of connector openings, for which the first set of connector openings is provided with an electrically conductive material for coupling at least two printed circuit board units.

Example 17 may include the printed circuit board connector of example 16 and/or any other example disclosed herein, which further includes a second set of connector openings for providing alignment with openings in connecting portions of the two printed circuit board units.

Example 18 may include the printed circuit board connector of example 16 and/or any other example disclosed herein, for which the printed circuit board connector is made of a composite material composed of woven fiberglass cloth with an epoxy resin binder.

Example 19 may include the printed circuit board connector of example 18 and/or any other example disclosed herein, for which the composite material has a coefficient of thermal expansion that is compatible with the two printed circuit board units.

Example 20 may include the printed circuit board connector of example 16 and/or any other example disclosed herein, for which the printed circuit board connector is a molded array solder connection interposer.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A printed circuit board assembly comprising:
a plurality of printed circuit board units; and
a board connector for joining at least two of the plurality of printed circuit board units, the board connector comprises:
a first surface and an opposing second surface; and
a plurality of openings, wherein the plurality of openings comprises a first set of connector openings for providing electrical connections between at least two plurality of printed circuit board units.

2. The printed circuit board assembly of claim 1, wherein the plurality of printed circuit board units comprises:
a first printed circuit board unit having a first connecting portion, wherein the first connecting portion of the first printed circuit board unit is electrically coupled to the first surface of the board connector; and
a second printed circuit board unit having a second connecting portion, wherein the second connecting portion of the second printed circuit board unit is electrically coupled to the second surface of the board connector.

3. The printed circuit board assembly of claim 2,
wherein the first connecting portion comprises a first set of connecting portion openings for alignment and attachment with the board connector;
wherein the second connecting portion comprises a second set of connecting portion openings for providing alignment and attachment with the board connector;
wherein the board connector further comprises a second set of connector openings that is aligned with both the first set of connecting portion openings in the first connecting portion of the first printed circuit board unit and the second set of connecting portion openings in the second connecting portion of the second printed circuit board unit.

4. The printed circuit board assembly of claim 3, further comprises a plurality of alignment members,
wherein the first set of connecting portion openings, the second set of connector openings, and the second set of connecting portion openings are aligned to form a set of stacked openings, and
wherein the plurality of alignment members is positioned in the set of stacked openings.

5. The printed circuit board assembly of claim 1, wherein the plurality of printed circuit board units comprises:
a first printed circuit board unit having a first connecting portion, wherein the first connecting portion is electrically coupled to the first surface of the board connector; and
a second printed circuit board unit having a second connecting portion, wherein the second connecting portion is electrically coupled to the first surface of the board connector.

6. The printed circuit board assembly of claim 5,
wherein the first connecting portion comprises a first set of connecting portion openings for alignment and attachment with the board connector;
wherein the second connecting portion comprises a second set of connecting portion openings for providing alignment and attachment with the board connector;
wherein the board connector further comprises a second set of connector openings that is aligned with both the first set of connecting portion openings in the first connecting portion of the first printed circuit board unit and the second set of connecting portion openings in the second connecting portion of the second printed circuit board unit.

7. The printed circuit board assembly of claim 6, further comprises a bridge board having a plurality of bridge board openings, wherein the bridge board is positioned on the second surface of the board connector.

8. The printed circuit board assembly of claim 7, further comprises a plurality of alignment members,
wherein the first set of connecting portion openings, a first portion of the second set of connector openings, and a first portion of the plurality of bridge board openings are aligned to form a first set of stacked openings, and
wherein the second set of connecting portion openings, a second portion of the second set of connector openings, and a second portion of the plurality of bridge board openings are aligned to form a second set of stacked openings, and
wherein the plurality of alignment members is positioned in the first and second stacked openings.

9. The printed circuit board assembly of claim 2, wherein the first printed circuit board unit comprises a central processing unit.

10. The printed circuit board assembly of claim 9, wherein the second printed circuit board unit comprises a discrete graphics processing unit or d-GPU.

11. The printed circuit board assembly of claim 1, wherein the plurality of printed circuit board units comprises at least three printed circuit board units for providing electrical connections and mechanical support to electrical components for parallel pre-fix scan operations.

12. The printed circuit board assembly of claim 1, further comprises an electrically conductive material filling the first set of openings in the board connector, wherein the electrically conductive material protrudes beyond the first and second surfaces of the board connector.

13. A method comprising:
forming a first printed circuit board unit with a first connecting portion;
forming a second printed circuit board unit with a second connecting portion;
forming a printed circuit board connector having a first surface and an opposing second surface;
electrically coupling the first connecting portion of the first printed circuit board unit with the first surface of the printed circuit board connector; and
electrically coupling the second connection portion of the second printed circuit board unit with the first surface or the second surface of the printed circuit board connector.

14. The method of claim 13, further comprises:
forming openings in the print circuit board connector; and
filling the openings with an electrically conductive material, wherein the electrically conductive material protrudes beyond the first and second surfaces of the printed circuit board connector.

15. The method of claim 13, further comprises forming openings for alignment in the first connecting portion of the first printed circuit board unit, the second connection portion of the second printed circuit board unit, and the printed circuit board connector;
aligning the openings in the first connecting portion of the first printed circuit board unit with the openings in the printed circuit board connector; and
aligning the openings in the second connecting portion of the second printed circuit board unit with the openings in the printed circuit board connector.

16. A printed circuit board connector comprising:
a first surface and an opposing second surface;
a plurality of openings formed in the printed circuit board connector, wherein the plurality of openings comprises a first set of connector openings, wherein the first set of connector openings is provided with an electrically conductive material for coupling at least two printed circuit board units.

17. The printed circuit board connector of claim 16, wherein the plurality of openings further comprises a second set of connector openings for providing alignment with openings in connecting portions of the two printed circuit board units.

18. The printed circuit board connector of claim 16, wherein the printed circuit board connector is made of a composite material composed of woven fiberglass cloth with an epoxy resin binder.

19. The printed circuit board connector of claim 18, wherein the composite material has a coefficient of thermal expansion that is compatible with the two printed circuit board units.

20. The printed circuit board connector of claim 16, wherein the printed circuit board connector is a molded array solder connection interposer.
